(19) United States
(12) Patent Application Publication
(10) Pub. No.: US 2018/0033344 A1
(43) Pub. Date: Feb. 1, 2018

(54) A FLEXIBLE DISPLAY SCREEN AND TV SET THEREOF

(71) Applicant: SHENZHEN SKYWORTH-RGB ELECTRONIC CO., LTD., Shenzhen (CN)

(72) Inventors: Weixiong CHEN, SHENZHEN (CN); Lingchao HU, SHENZHEN (CN); Qianzheng XU, SHENZHEN (CN); Biao CHU, SHENZHEN (CN)

(21) Appl. No.: 15/510,257

(22) PCT Filed: Feb. 23, 2016
(86) PCT No.: PCT/CN2016/074304

§ 371 Date: Mar. 10, 2017

(30) Foreign Application Priority Data
Jan. 6, 2016 (CN) 201610002719.8

(51) Int. Cl. G09F 9/30; G06F 1/16; H04N 5/64; G09F 19/02

(52) U.S. Cl. CPC G09F 9/30; G09F 19/02; G06F 1/1652; H04N 5/64; H01L 51/0097

(57) ABSTRACT

The present invention provides a flexible display screen, wherein, it comprises a screen and an arc tube applied to switching the screen between a curved shape and a flat shape; a plurality of spacing sockets are arranged on a back of the screen, a plurality of spacing holes are arranged in the spacing sockets, each of the arc tube is closely matching the spacing hole and rotatable around the spacing hole under an action of an external force; the arc tube has an arc shaped surface, when the arc shaped surface of the are tube faces toward a vertical direction, the screen is in a flat shape, while the arc shaped surface of the arc tube faces toward a horizontal direction, the screen becomes a curved shape. The present invention may adjust the bending curvature of the display screen flexibly as requirement, making the display screen switch freely between the curved shape and the flat shape, giving the viewer a best effect of visual angle, which has effectively solved a problem that a display screen may only be either a flat shape or a curved shape, and making a user not be able to switch in between as requirement; also, the present invention owns a simple structure, being convenient and practical.

### CROSS-REFERENCES TO RELATED APPLICATIONS

This application is a national stage application of PCT Patent Application No. PCT/CN2016/074304, filed on Feb. 23, 2016, which claims priority to Chinese Patent Application No. 201610002719.8, filed on Jan. 6, 2016, the content of all of which is incorporated herein by reference.

### FIELD OF THE INVENTION

The present invention relates to the field of a display screen, and, more particularly, to a flexible display screen and TV set thereof.

### BACKGROUND

Currently on market, display screens of most TV sets are straight flat shaped, which are more suitable for a plurality of people to watch at a same time, however, it may not provide a viewer a best angle of view. With a progress of science and technology, a curved display screen has appeared gradually on market, whose best visual effect is at a central position; however, its visual range is relatively narrow, and it is not suitable for a plurality of people to watch at the same time.

Therefore, the current technology needs to be improved and developed.

### BRIEF SUMMARY OF THE DISCLOSURE

According to the above described defects in the prior art, the purpose of the present invention is providing a flexible display screen and TV set thereof, which may adjust a bending curvature of the display screen flexibly as required, making the display screen switch freely between a curved shape and a flat shape, giving a viewer the best angle of view, also, it owns a simple structure, while being convenient and practical.

In order to achieve the above mentioned goals, the technical solution of the present invention to solve the technical problems is as follows:

A flexible display screen, wherein, it comprises a screen and an arc tube applied to switching the screen between a curved shape and a flat shape; a plurality of spacing sockets are arranged on a back of the screen, a plurality of spacing holes are arranged in the spacing sockets, each of the arc tube is closely matching the spacing hole and rotatable around the spacing hole under an action of an external force; the arc tube has an arc shaped surface, when the arc shaped surface of the arc tube faces toward a vertical direction, the screen is in a flat shape, while the arc shaped surface of the are tube faces toward a horizontal direction, the screen becomes a curved shape.

The flexible display screen, wherein, the display screen further comprises a driving device, applied to driving the arc tube to rotate, the driving device drives the arc tube to rotate through a worm-gear transmission pair, the worm-gear transmission pair includes a worm gear set in the are tube and a worm set in a mounting seat, which is fixedly arranged on a back of the screen, the worm gear and the worm are intermeshing, the driving device connects to the worm and drives the worm to rotate.

The flexible display screen, wherein, the driving device is a manual driving device, including a rotatable plate, the rotatable plate includes a rotation axis which connects to the worm and drives the worm to rotate.

The flexible display screen, wherein, a through-hole is arranged in the mounting seat, the rotation axis penetrates through the through-hole and connects with the worm.

The flexible display screen, wherein, a handle is arranged on the rotation plate, to facilitate a manual driving.

The flexible display screen, wherein, the driving device is a motor, an output shaft of the motor connects to the worm and drives the worm to rotate.

The flexible display screen, wherein, the mounting seat is arranged in the middle of the screen, a plurality of the spacing sockets are arranged on both sides of the mounting seat symmetrically.

The flexible display screen, wherein, the screen is a flexible screen.

The flexible display screen, wherein, the spacing hole is a kidney shaped hole, a horizontal width of the spacing hole is matching a diameter of the arc tube, a vertical width of the spacing hole is larger than the diameter of the arc tube.

A TV set, wherein, it includes the flexible display screen described above.

The present invention provides a flexible display screen and TV set thereof, since adopting an arc tube set in the back of the screen, the arc tube is closely matching a spacing hole and rotatable around the spacing hole under an action of an external force, which may adjust the bending curvature of the display screen flexibly as requirement, making the display screen switch freely between the curved shape and the flat shape, giving the viewer a best effect of visual angle, which has effectively solved a problem that a display screen may only be either a flat shape or a curved shape, and making a user not be able to switch in between as required; also, the present invention owns a simple structure, being convenient and practical.

### BRIEF DESCRIPTION OF THE DRAWINGS

FIG. 1 illustrates a structural diagram of a flexible display screen as provided in the present invention.

FIG. 2 illustrates a decomposition diagram of the flexible display screen as provided in the present invention.

FIG. 3 illustrates a partial assembly diagram of an arc tube and a spacing socket as provided in the present invention.

FIG. 4 illustrates a partial assembly diagram of a worm-gear transmission pair as provided in the present invention.

FIG. 5 illustrates a schematic diagram on a flexible display screen in a flat shape as provided in the present invention.

FIG. 6 illustrates a top view of FIG. 5.

FIG. 7 illustrates a schematic diagram on the flexible display screen in a curved shape as provided in the present invention.

FIG. 8 illustrates a top view of FIG. 7.

### DETAILED DESCRIPTION OF EMBODIMENTS

The present invention provides a flexible display screen and TV set thereof, in order to make the purpose, technical solution and the advantages of the present invention clearer and more explicit, further detailed descriptions of the present invention are stated here, referencing to the attached drawings and some Preferably embodiments of the present invention. It should be understood that the detailed embodiments of the invention described here are used to explain the present invention only, instead of limiting the present invention.

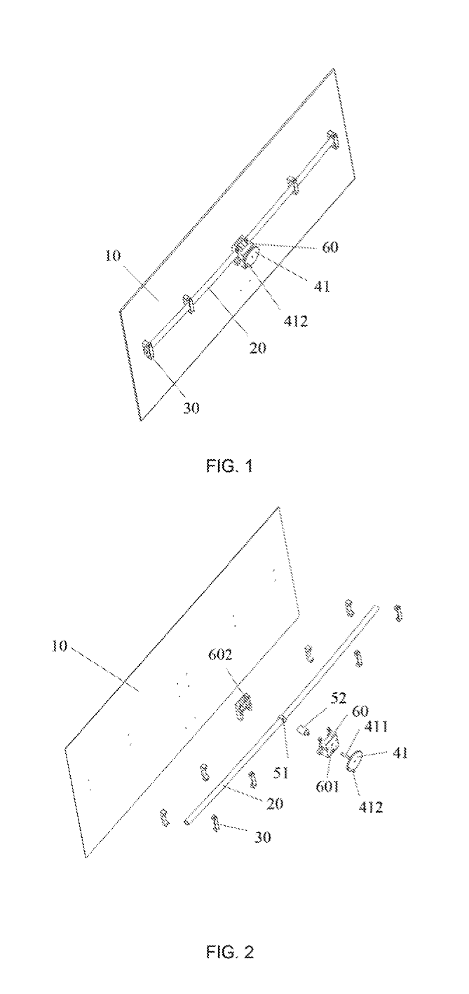

Referencing to FIG. 1 and FIG. 2, wherein, FIG. 1 illustrates a structural diagram of a flexible display screen as provided in the present invention. FIG. 2 illustrates a decomposition diagram of the flexible display screen as provided in the present invention. The present invention provides a flexible display screen, comprising a screen 10 and an arc tube 20 applied to switching the screen 10 between a curved shape and a flat shape; a plurality of spacing sockets 30 are arranged on a back of the screen 10, a plurality of spacing holes 301 are arranged in the spacing sockets 30, each of the arc tube 20 is closely matching the spacing hole 301 and rotatable around the spacing hole 301 under an action of an external force; the arc tube 20 has an arc shaped surface 21, when the arc shaped surface 21 of the arc tube 20 faces toward a vertical direction, the screen 10 is in a flat shape, while the arc shaped surface 21 of the arc tube 20 faces toward a horizontal direction, the screen 10 becomes a curved shape.

Wherein, the present invention flexibly adjusts a bending curvature of the screen 10 through the arc tube 20, making the display screen switch freely between the curved shape and the flat shape, giving a viewer a best angle of view, satisfying a different requirement of the viewer, giving a better experience, and being more practical and humanized, matching a market requirement better, while it owns a simple structure and a convenient application; which has effectively solved a problem in the prior art, that a display screen may only be either a flat shape or a curved shape, and making a user not be able to switch in between as requirement.

Preferably, the display screen further comprises a driving device, applied to driving the arc tube 20 to rotate, the driving device drives the arc tube 20 to rotate through a worm-gear transmission pair. As shown in FIG. 4, the worm-gear transmission pair includes a worm gear 51 set in the arc tube 20 and a worm 52 set in a mounting seat 60, which is fixedly arranged on a back of the screen 10, the worm gear 51 and the worm 52 are intermeshing, the driving device connects to the worm 52 and drives the worm 52 to rotate. Since the worm-gear transmission pair has an auto-lock function, when the driving device stops driving, the screen 10 may keep its state. A transmission through a worm-gear transmission pair, may make the bending curvature of the screen 10 be adjusted freely, which may be adjusted to a best visual state as required, when the viewer is watching the display screen, which is more humanized.

It should be noted that, a transmission mode of the driving device is not limited thereto, in other preferable embodiments of the present invention, the driving device may transmit through a gear transmission pair or a gear and rack transmission pair. When the driving device is driving through the gear transmission pair, a first gear may be sleeved on the arc tube 20, and a second gear intermeshes the first gear, when driving the second gear to rotate, the first gear is also driven to rotate, and making the arc tube 20 rotate. When the driving device is driving through the gear and rack transmission pair, a gear may be sleeved on the arc tube 20, while the rack intermeshes and connects to the gear, through driving the rack to move linearly, driving the gear to rotate, and making the are tube 20 rotate.

Preferably, the driving device is a manual driving device, including a rotatable plate 41, by which, a more effective result may be achieved, the rotatable plate 41 includes a rotation axis 411 which connects to the worm 52 and drives the worm 52 to rotate. Specifically, a through-hole 601 is arranged in the mounting seat 60, the rotation axis 411 penetrates through the through-hole 601 and connects with the worm 52. Preferably, in order to facilitate a manual driving, a handle 412 is further arranged on the rotation plate 41, through rotating the handle 412, making the rotation plate 41 rotate, so as to driving the arc tube 20 rotate through the worm-gear transmission pair, before achieving a goal of adjusting the bending curvature of the screen 10.

It should be noted that the driving mode of the driving device is not limited thereto, in other preferable embodiments of the present invention, the driving device may also be a motor, whose an output shaft connects to the worm 52 and drives the worm 52 rotate. Through a rotation of the motor, drives the worm 52 rotate, so as to make the worm gear 51 rotate, and finally achieve the rotation of the arc tube 20, and achieve the goal of adjusting the bending curvature of the screen 10.

Preferably, the mounting seat 60 is arranged in the middle of the screen 10, a plurality of the spacing sockets 30 are arranged on both sides of the mounting seat 60 symmetrically, so as to keep the bending curvature a same in every position of the screen 10. In the present embodiment, there are four spacing sockets 30, which are distributed symmetrically on both sides of the mounting seat 60. It should be noted that, a number of the spacing sockets 30 may be decided according to a size of the screen 10, in other preferable embodiments of the present invention, the number of the spacing sockets 30 may be six, eight or more.

Preferably, the mounting seat 10 has a rotating hole 602, the arc tube 20 penetrates through the rotating hole 602.

Preferably, the screen 10 is a flexible screen, so as to make the screen 10 change following a change of the arc tube 20. The arc tube 20 is a steel arc tube, owning a good strength of structure.

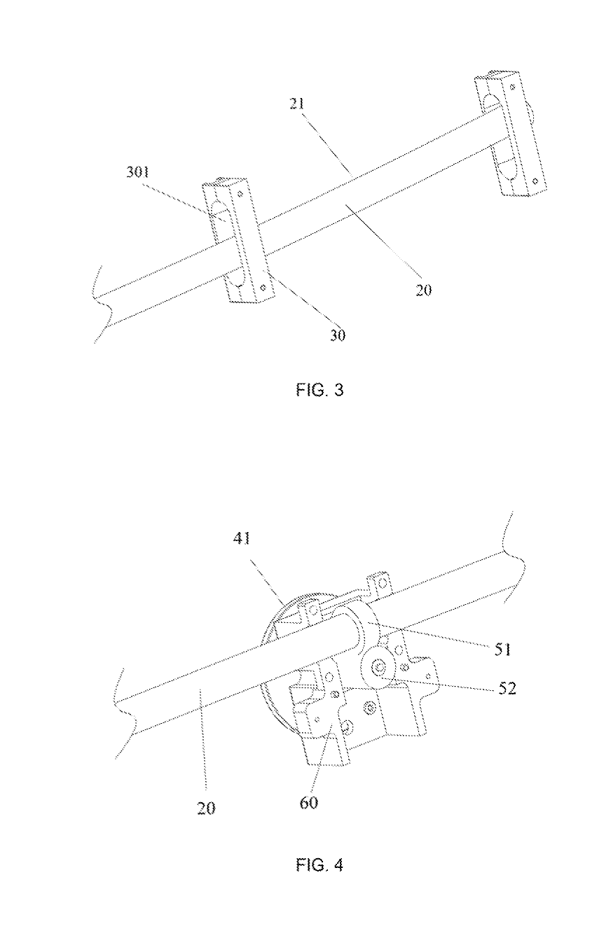

Preferably, shown as FIG. 3, the spacing hole 301 is a kidney shaped hole, a horizontal width of the spacing hole 301 is matching a diameter of the arc tube 20, a vertical width of the spacing hole 301 is larger than the diameter of the arc tube 20, so as to make the horizontal width of the spacing hole 301 satisfy a horizontal direction movement when the arc tube 20 is changing, and meanwhile, make the screen 10 generate a deformation through the spacing socket 30, when the arc tube 20 is changing.

A process of use of the present invention is as follows:

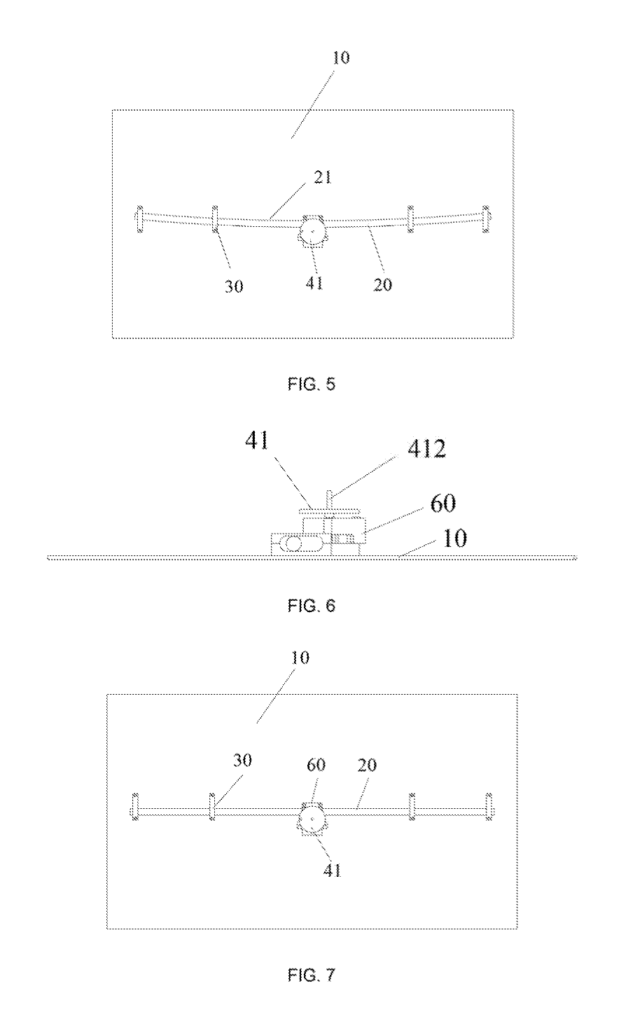

When it is needed to adjust the screen 10 of the display screen into a flat shape, first, through rotating the handle 412 manually, driving the rotation plate 41 to rotate, then through the transmission by the worm-gear pair, driving the arc tube rotate; when the arc shaped surface 21 of the arc tube 20 faces toward a vertical direction, stop driving, and finally make the screen 10 keep a straight flat state (as shown in FIG. 5 and FIG. 6).

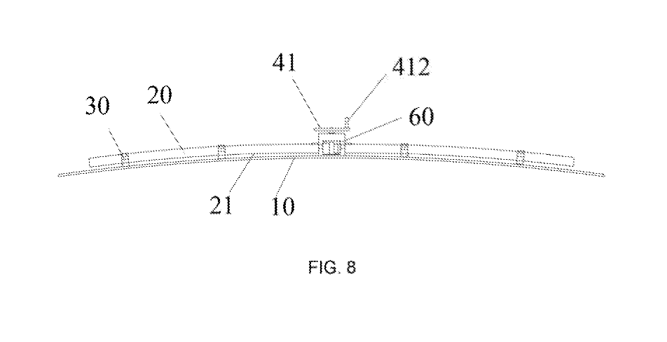

When it is needed to adjust the screen 10 of the display screen into a curved shape, the handle 412 may be rotated manually in a reverse direction, through the transmission by the worm-gear pair, the arc tube 20 is driven to rotate reversely, so as to make the screen 10 transit from the straight shape to the curved shape, and when the arc shaped surface 21 of the arc tube 20 is turning to the horizontal direction, the screen 10 owns the maximum bending curvature. (shown as FIG. 7 and FIG. 8).

The present invention further provides a TV set, the TV set includes a flexible display screen, whose specific structure may be referencing to the embodiments on the flexible display screen in the present invention and a plurality of descriptions from FIG. 1 to FIG. 8, no more descriptions are repeated hereof.

It should be understood that, the application of the present invention is not limited to the above examples listed. Ordinary technical personnel in this field can improve or change the applications according to the above descriptions, all of these improvements and transforms should belong to the scope of protection in the appended claims of the present invention.

What is claimed is:

1. A flexible display screen, wherein, it comprises a screen and an arc tube applied to switching the screen between a curved shape and a flat shape; a plurality of spacing sockets are arranged on a back of the screen, a plurality of spacing holes are arranged in the spacing sockets, each of the arc tube is closely matching the spacing hole and rotatable around the spacing hole under an action of an external force; the arc tube has an arc shaped surface, when the arc shaped surface of the arc tube faces toward a vertical direction, the screen is in a flat shape, while the arc shaped surface of the arc tube faces toward a horizontal direction, the screen becomes a curved shape.

2. The flexible display screen according to claim 1, wherein, the screen is a flexible screen.

3. The flexible display screen according to claim 1, wherein, the spacing holes are kidney shaped holes, a horizontal width of the spacing hole is matching a diameter of the arc tube, a vertical width of the spacing hole is larger than the diameter of the arc tube.

4. A flexible display screen, wherein, it comprises a screen and an arc tube applied to switching the screen between a curved shape and a flat shape; a plurality of spacing sockets are arranged on a back of the screen, a plurality of spacing holes are arranged in the spacing sockets, each of the arc tube is closely matching the spacing hole and rotatable around the spacing hole under an action of an external force; the arc tube has an arc shaped surface, when the arc shaped surface of the arc tube faces toward a vertical direction, the screen is in a flat shape, while the arc shaped surface of the arc tube faces toward a horizontal direction, the screen becomes a curved shape;
the display screen further comprises a driving device, applied to driving the arc tube to rotate, the driving device drives the arc tube to rotate through a worm-gear transmission pair, the worm-gear transmission pair includes a worm gear set in the arc tube and a worm set in a mounting seat, which is fixedly arranged on a back of the screen, the worm gear and the worm are intermeshing, the driving device connects to the worm and drives the worm to rotate.

5. The flexible display screen according to claim 4, wherein, the driving device is a manual driving device, including a rotatable plate, the rotatable plate includes a rotation axis which connects to the worm and drives the worm to rotate.

6. The flexible display screen according to claim 5, wherein, a through-hole is arranged in the mounting seat, the rotation axis penetrates through the through-hole and connects with the worm.

7. The flexible display screen according to claim 5, wherein, a handle is arranged on the rotation plate, to facilitate a manual driving.

8. The flexible display screen according to claim 6, wherein, a handle is arranged on the rotation plate, to facilitate a manual driving.

9. The flexible display screen according to claim 8, wherein, the screen is a flexible screen.

10. The flexible display screen according to claim 9, wherein, the driving device is a motor, an output shaft of the motor connects to the worm and drives the worm to rotate.

11. The flexible display screen according to claim 4, wherein, the driving device is a motor, an output shaft of the motor connects to the worm and drives the worm to rotate.

12. The flexible display screen according to claim 4, wherein, the mounting seat is arranged in the middle of the screen, a plurality of the spacing sockets are arranged on both sides of the mounting seat symmetrically.

13. The flexible display screen according to claim 4, wherein, the screen is a flexible screen.

14. The flexible display screen according to claim 4, wherein, the spacing hole is a kidney shaped hole, a horizontal width of the spacing hole is matching a diameter of the arc tube, a vertical width of the spacing hole is larger than the diameter of the arc tube.

15. A TV set, wherein, it includes the flexible display screen described in claim 1.
